(19) United States
(12) Patent Application Publication
(10) Pub. No.: US 2015/0311233 A1
(43) Pub. Date: Oct. 29, 2015

(54) TFT ARRAY SUBSTRATE AND METHOD FOR MANUFACTURING THE SAME

(71) Applicant: EverDisplay Optronics (Shanghai) Limited, Shanghai (CN)

(72) Inventors: Lung Pao Hsin, Shanghai (CN); Tianwang Huang, Shanghai (CN)

(21) Appl. No.: 14/669,809

(22) Filed: Mar. 26, 2015

(30) Foreign Application Priority Data
Apr. 25, 2014 (CN) 201410170902.X

(51) Int. Cl. H01L 27/12; H01L 27/32; H01L 29/66

(52) U.S. Cl. CPC H01L 27/1225; H01L 29/66969; H01L 27/1259; H01L 27/1218; H01L 27/3244

(57) ABSTRACT

The embodiments of the present disclosure relate to a TFT array substrate and method for manufacturing the same, including: forming a gate electrode on a transparent substrate, and forming a first insulating layer on the gate electrode covering the gate electrode and transparent substrate; forming a patterned IGZO layer on the first insulating layer; processing the IGZO layer to form source region and drain region; forming a second insulating layer on the IGZO layer; and forming contacting holes communicating with the source region and the drain region in the second insulating layer, and depositing electrodes in the contacting holes. The present disclosure need not form the second metal layer so as to omit photolithography and etching processes for forming the second metal layer, which may shorten the manufacturing process, improve the efficiency, and reduce dimension of the TFT.

### CROSS REFERENCE TO RELATED APPLICATIONS

This application claims the priority to and the benefit of Chinese Patent Application No. 201410170902.X, filed Apr. 25, 2014 and entitled “TFT array substrate and method for manufacturing the same”, which is incorporated herein by reference in its entirety.

### TECHNICAL FIELD

The present disclosure relates generally to the technical field of TFT array substrate and method for manufacturing the same, which may be used for AMOLED.

### BACKGROUND

Nowadays, low temperature poly-silicon (LTPS) and amorphous silicon (a-Si) are commonly adopted to be semiconductor materials to manufacture a thin film transistor (TFT) array substrate of active-matrix organic light-emitting diode (AMOLED). The method for manufacturing mainly includes processes of film coating, photolithography and etching. The flowchart of manufacturing the TFT array substrate is shown in FIG. 1 and FIG. 2.

FIG. 1 illustrates a flowchart of manufacturing the TFT array substrate which uses LTPS as the semiconductor material, which includes the following steps:

S1′: forming a LTPS semiconductor layer on a glass substrate;

S2′: forming a gate electrode insulating layer and a first metal layer having a gate electrode on the LTPS semiconductor layer;

S3′: forming a first insulating layer on the first metal layer to provide an insulation protection for the first metal layer, and forming two first contacting holes on the first insulating layer which pass through the first insulating layer;

S4′: forming a second metal layer which has a source region and a drain region on the first insulating layer;

S5′: forming a second insulating layer on the second metal layer to provide an insulation protection for the second metal layer, and forming two second contacting holes on the second insulating layer which correspond to the position of the first contacting holes;

S6′: depositing metal material in the first and second contacting holes for manufacturing electrodes;

S7′: forming a third insulating layer on the electrodes to provide an insulation protection for the electrodes.

FIG. 2 illustrates a flowchart of manufacturing the TFT array substrate which uses a-Si as the semiconductor material, which includes the following steps:

S1″: forming a first metal layer having gate electrode on the glass substrate, and forming a first insulating layer on the first metal layer to provide an insulation protection for the first metal layer;

S2″: forming an a-Si semiconductor layer on the first insulating layer;

S3″: forming a second metal layer having source region and drain region on the a-Si semiconductor layer;

S4″: forming a second insulating layer on the second metal layer to provide an insulation protection for the second metal layer, and forming two contacting holes on the second insulating layer which contact the source region and drain region;

S5″: depositing metal material in the two contacting holes for manufacturing electrodes;

S6″: forming a third insulating layer on the electrodes to provide an insulation protection for the electrodes.

However, during the current process for manufacturing TFT array substrate of AMOLED, it is required to repeat the above steps, which not only consumes long time and much human labor, but also affects the apparatus effectiveness.

### SUMMARY

The embodiments of the present disclosure provide a TFT array substrate and method for manufacturing the same, which, in part, may shorten the manufacturing process, improve the apparatus effectiveness, and reduce dimension of the TFT array substrate.

In one aspect, the present disclosure provides a method for manufacturing a thin film transistor (TFT) array substrate comprising:

forming a gate electrode on a transparent substrate, and forming a first insulating layer on the gate electrode covering the gate electrode and the transparent substrate;

forming a patterned indium gallium zinc oxide (IGZO) layer on the first insulating layer;

processing the IGZO layer to form a source region and a drain region;

forming a second insulating layer on the processed IGZO layer; and

forming contacting holes communicating with the source region and the drain region in the second insulating layer, and depositing electrodes in the contacting holes.

In another aspect, the present disclosure provides A TFT array substrate, comprising:

a transparent substrate;

a gate electrode formed on the transparent substrate;

a first insulating layer formed on the gate electrode;

an IGZO layer formed on the first insulating layer adapted for a TFT;

a second insulating layer formed on the IGZO layer in which contacting holes are formed to communicate with the IGZO layer; and

electrodes provided in the contacting holes;

wherein, the IGZO layer includes a channel region, a source region and a drain region which are self-aligned with the gate electrode, and resistance of the source region and resistance of drain region are smaller than that of the channel region.

Some advantageous effects of the embodiments of the present disclosure may include the following:

In the present disclosure, the semiconductor layer is made of indium gallium zinc oxide (IGZO) which has a conductor property under the irradiation of ultraviolet (UV) light, by means of this, source region, drain region, ohmic contact and other electric wiring can be realized simultaneously, thereby omitting the step of forming the second metal layer having the source region and drain region in the traditional process. The present disclosure need not to form the second metal layer so as to omit photolithography and etching processes for forming the second metal layer, which may shorten the manufacturing process, improve the efficiency, and reduce dimension of the TFT.

The foregoing summary is not intended to summarize each potential embodiment or every aspect of the present disclosure.

### BRIEF DESCRIPTION OF THE DRAWINGS

FIG. 1 is an illustrative flowchart of manufacturing the TFT array substrate which uses LTPS as the semiconductor material according to the prior art;

FIG. 2 is an illustrative flowchart of manufacturing the TFT array substrate which uses a-Si as the semiconductor material according to the prior art;

FIG. 3 is an illustrative flowchart of manufacturing the TFT array substrate according to an embodiment of the present disclosure;

FIG. 4 is an detailed illustrative flowchart of a part of step in FIG. 3; and

FIG. 5A to FIG. 5F illustrate schematic views corresponding to the steps S1 to S6 in FIG. 3.

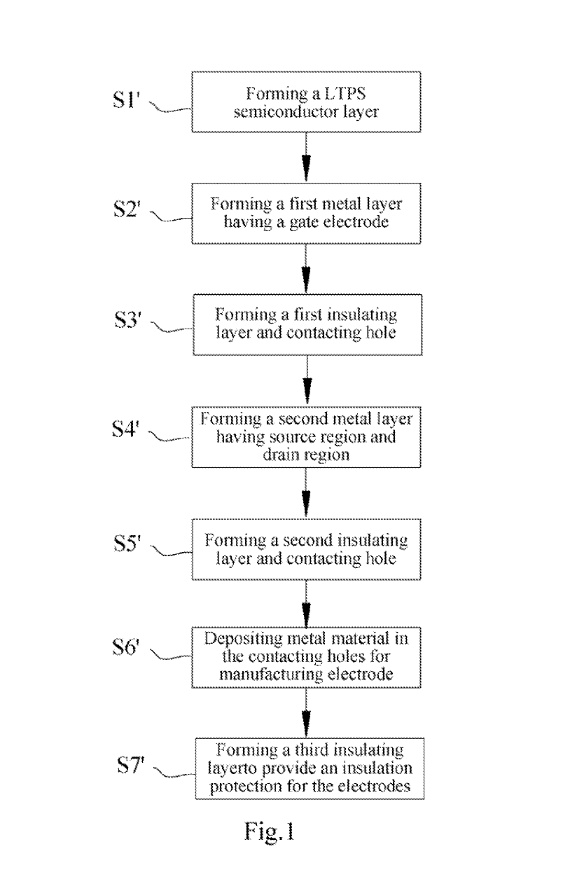

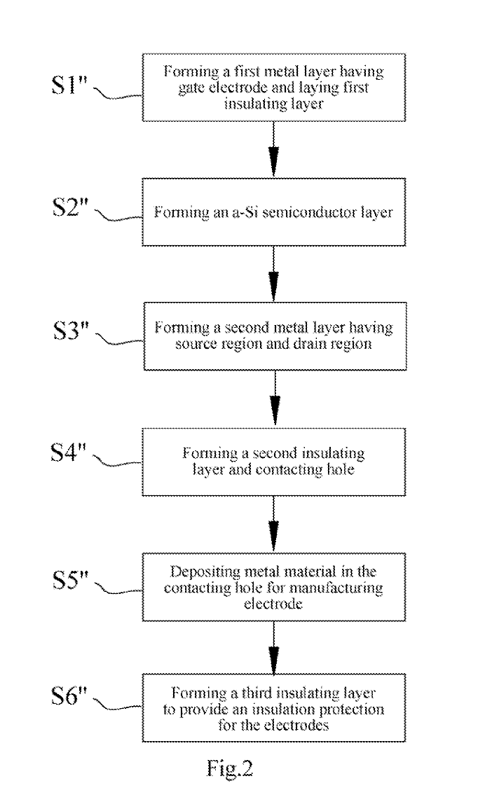

Specific embodiments in this disclosure have been shown by way of example in the foregoing drawings and are hereinafter described in detail. The figures and written description are not intended to limit the scope of the inventive concepts in any manner. Rather, they are provided to illustrate the inventive concepts to a person skilled in the art by reference to particular embodiments.

### DETAILED DESCRIPTION

Hereinafter, implementations of methods and apparatuses for processing short messages according to the embodiments of the present disclosure will be described in detail in conjunction with the drawings.

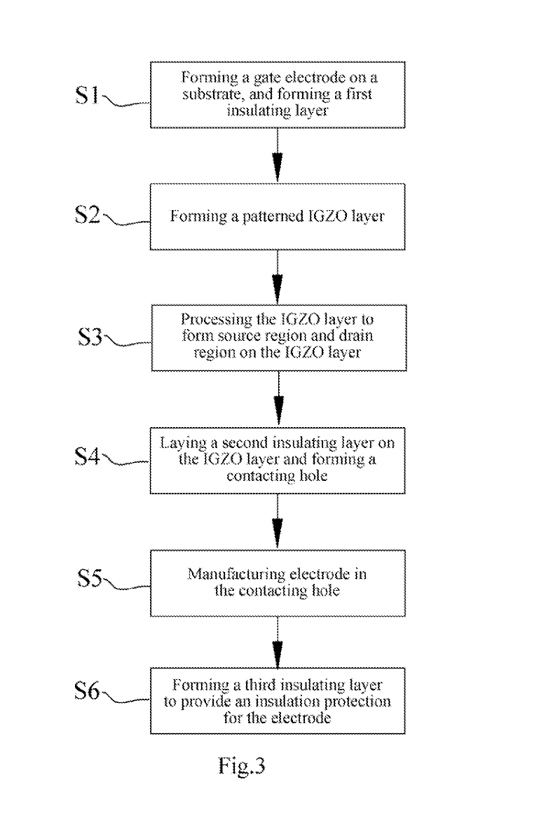

FIG. 3 is an illustrative flowchart of manufacturing the TFT array substrate according to an embodiment of the present disclosure. As shown in FIG. 3, the method for manufacturing the TFT array substrate includes the steps as follows.

S1: forming a first metal layer which is patterned and has a gate electrode G on a transparent substrate 10, and forming a first insulating layer 20 on the first metal layer covering the first metal layer having the gate electrode G; the first metal layer may be formed of Mo layer, Al layer, Ti layer, Ag layer, or ITO layer, or the combination of the above layer.

S2: forming a patterned indium gallium zinc oxide (IGZO) layer 30 on the first insulating layer 20;

S3: processing the IGZO layer 30 to form source region and drain region on the IGZO layer 30;

S4: forming a second insulating layer 40 on the IGZO layer 30 processed in the above step to provide an insulation protection for the IGZO layer 30, and forming contacting hole 41 communicating with the IGZO layer on the second insulating layer 40;

S5: depositing metal material in the contacting hole 41 for manufacturing electrode 50 made of Mo, Al, Ti, Ag, or ITO, or a combination of layers of said respective materials;

S6: forming a third insulating layer 60 on the electrode 50 to provide an insulation protection for the electrode 50.

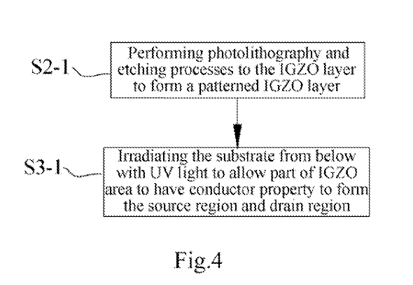

As shown in FIG. 4, in an embodiment, step S2 of forming a patterned indium gallium zinc oxide (IGZO) layer 30 on the first insulating layer 20 includes:

S2-1: forming an IGZO material layer and performing photolithography and etching processes to the IGZO material layer to form the patterned IGZO layer 30 on the gate electrode G;

Step S3 of processing the IGZO layer 30 to form source region and drain region on the IGZO layer 30 includes:

S3-1: irradiating the substrate 10 from below with ultraviolet (UV) light or light with a frequency band closed to that of UV light. Due to the block of the gate electrode G, an area of IGZO layer which is located on the gate electrode G and not irradiated by light still has semiconductor property, while other areas of IGZO layer which is irradiated has conductor property. During this step, the source region and drain region may be formed in IGZO pattern.

Herein, photolithography process means transferring main pattern on a mask to photosensitive material, irradiating the photosensitive material by light through the mask, and dissolving or retaining the irradiated part of photosensitive material in manner of soaking by solvent. A photoresist pattern formed by the above process may be identical or complementary with that of the mask. The photolithography process is commonly known by the person skilled in the art and the detailed description is omitted herein.

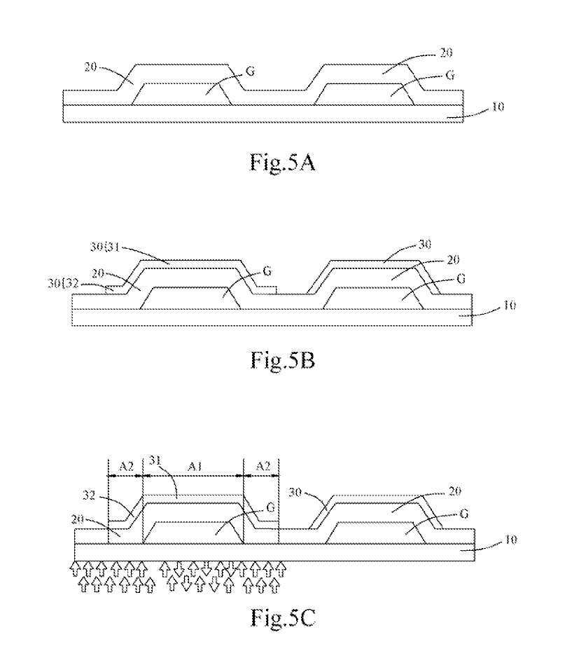

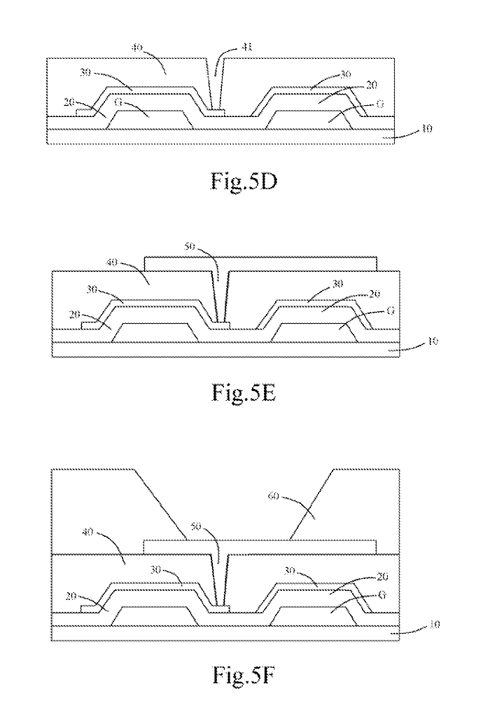

FIG. 5A to FIG. 5F illustrate schematic views corresponding to the steps S1 to S6 in FIG. 3, which show each step of manufacturing the TFT array substrate and will be explained as follows respectively.

As shown in FIG. 5A, in step S1, firstly, forming a first metal layer on the substrate 10, and patterning the first metal layer by photolithography and etching processes to form the gate electrode G. And forming the first insulating layer 20 on the first metal layer covering the substrate 10 and the gate electrode G;

And then, as shown in FIG. 5B, forming a patterned IGZO layer 30 on the first metal layer by deposition, photolithography and etching processes. The IGZO layer 30 is in an island-like shape formed on the first insulating layer 20 and includes a first area 31 over and corresponding to the position of the gate electrode G and a second area 32 adjacent to the first area 31 and not corresponding to the position of the gate electrode G.

Next, as shown in FIG. 5C, irradiating the substrate 10 from below with UV light or light with a frequency band closed to that of UV light, which allows the non-irradiated first area 31 in IGZO layer 30 over the gate electrode G to have semiconductor property due to the block of the gate electrode G, while the irradiated second area 32 not corresponding to the position of the gate electrode G to have conductor property. Therefore, during this step, the source region and drain region may be formed in manner of self-alignment. One of the first area and second area 31, 32 is formed into the source region, and the other is formed into the drain region. For example, if the first area 31 is formed into the source region, then the second area 32 is formed into the drain region; if the second area 32 is formed into the source region, then the first area 31 is formed into the drain region.

The light with a frequency band closed to that of UV light refers to a light with wavelength within a range of 350 nm to 450 nm. UV light or light with a frequency band closed to that of UV light is by way of example only, it will be appreciated that those skilled in the art could use alternative light which is capable of converting irradiated IGZO material layer to have conductor property.

Subsequently, as shown in FIG. 5D, forming a second insulating layer 40 on the IGZO layer 30 irradiated in the above step to provide an insulation protection for the

IGZO layer 30, and forming the contacting hole 41 on the second insulating layer 40, which passes through the second insulating layer 40 and communicates with the source region and drain region of the IGZO layer 30.

And then, as shown in FIG. 5E, manufacturing electrode 50 in the contacting hole 41. In the present embodiment, the electrode is manufactured by depositing metal material.

Next, as shown in FIG. 5F, forming a third insulating layer 60 on the electrode 50 to provide an insulation protection for the electrode 50.

Furthermore, according to another embodiment, after forming the second insulating layer 40, a mask may be formed on the second insulating layer 40 which covers the IGZO layer 30 of TFT for blocking UV light and exposing a part of IGZO layer used for capacitor. A part of IGZO layer used for capacitor is irradiated from the top of the substrate 10 with UV light or light with a frequency band closed to that of UV light so as to have conductor property, thereby acting as an electrode of the capacitor.

In the above embodiments, the first, second and third insulating layers may be made of SiOx, SiNx, SiOxNy or organic material, which is not limited hereto. Meanwhile, materials of the first, second and third insulating layers need not be fully identical, for example, material of the first insulating layer may be SiOx, material of the second insulating layer may be SiOx and SiNx, and material of the third insulating layer may be SiNx.

As shown in FIG. 5F, the TFT array substrate manufactured according to the method of the present disclosure includes the substrate 10, the first metal layer having the gate electrode G, the first insulating layer 20 on the gate electrode G, the IGZO layer 30 on the first insulating layer 20 and having a channel region, source region and drain region, the second insulating layer 40 on the IGZO layer 30, and the electrode 50. The contacting hole 41 is formed in the second insulating layer 40 and communicating with the IGZO layer 30, and electrode 50 is disposed in the contacting hole 41.

The TFT array substrate further includes a capacitor with an electrode located at the same metal layer with the gate electrode G, and the other electrode made of the IGZO layer and located at the same metal layer with the IGZO used in TFT.[ [symbol] IGZO [symbol] TFT]

In an embodiment of the present disclosure, the IGZO layer 30 is provided with the source region and drain region. In an embodiment, the IGZO layer 30 includes a first area 31 on and corresponding to the position of the gate electrode G and a second area 32 adjacent to the first area 31. By the irradiation of UV light or light with a frequency band closed to that of UV light and with a wavelength smaller than 420 nm, the patterns of the source region and drain region are irradiated to have conductor property so as to form the source region and drain region. Due to the block of the gate electrode G, the first area 31 not irradiated still has semiconductor property.

In an embodiment of the TFT array substrate according to the present disclosure, the electrode 50 is formed by depositing metal material in the contacting hole. The TFT array substrate further includes a third insulating layer 60 on the electrode 50.

In conclusion, according to an embodiment of the present disclosure, the semiconductor layer is made of indium gallium zinc oxide (IGZO) which has a conductor property under the irradiation of UV light, by means of this, source region, drain region, ohmic contact, and other electric wiring can be achieved simultaneously, thereby omitting the step of forming the second metal layer having the source region and drain region in the traditional process. The present disclosure need not to form the second metal layer so as to omit photolithography and etching processes for forming the second metal layer, which may shorten the manufacturing process, improve the efficiency, and reduce dimension of the TFT. In addition, the TFT and capacitor may be formed simultaneously, thereby shortening the manufacturing process and improving the efficiency.

It should be noted that the above embodiments are only illustrated for describing the technical solution of the disclosure and not restrictive, and although the embodiments are described in detail by referring to the aforesaid embodiments, the skilled in the art should understand that the aforesaid embodiments can be modified and portions of the technical features therein may be equally changed, which does not depart from the spirit and scope of the technical solution of the embodiments of the disclosure.

What is claimed is:

1. A method for manufacturing a thin film transistor (TFT) array substrate comprising:
forming a gate electrode on a transparent substrate, and forming a first insulating layer on the gate electrode covering the gate electrode and the transparent substrate;
forming a patterned indium gallium zinc oxide (IGZO) layer on the first insulating layer;
processing the IGZO layer to form a source region and a drain region;
forming a second insulating layer on the processed IGZO layer; and
forming contacting holes communicating with the source region and the drain region in the second insulating layer, and depositing electrodes in the contacting holes.

2. The method for manufacturing a TFT array substrate according to claim 1, wherein the step of forming the patterned IGZO layer on the first insulating layer comprises:
forming an island-like shaped IGZO layer to cover the first insulating layer, the island-like shaped IGZO layer including a first area above the gate electrode and corresponding to the position of the gate electrode, and a second area adjacent to the first area.

3. The method for manufacturing a TFT array substrate according to claim 2, wherein the step of forming the patterned IGZO layer on the first insulating layer comprises:
forming an IGZO material layer and performing photolithography and etching processes to the IGZO material layer to form the patterned IGZO layer on the gate electrode.

4. The method for manufacturing a TFT array substrate according to claim 3, wherein the step of processing the IGZO layer to form the source region and the drain region comprises:
irradiating the transparent substrate from below to turn the second area to have conductor property after been irradiated, such that the source region and drain region are formed in manner of self-alignment.

5. The method for manufacturing a TFT array substrate according to claim 4, wherein the first area retains semiconductor property after the irradiating step.

6. The method for manufacturing a TFT array substrate according to claim 5, wherein the irradiating step is performed with UV light or light with a frequency band closed to that of UV light.

7. The method for manufacturing a TFT array substrate according to claim 1, further comprising:
after forming the second insulating layer, irradiating a part of IGZO layer from the top of the substrate to form an electrode of a capacitor.

8. The method for manufacturing a TFT array substrate according to claim 1, wherein the transparent substrate is glass substrate.

9. A TFT array substrate comprising:
a transparent substrate;
a gate electrode formed on the transparent substrate;
a first insulating layer formed on the gate electrode;
an IGZO layer formed on the first insulating layer;
a second insulating layer formed on the IGZO layer in which contacting holes are formed to communicate with the IGZO layer; and
electrodes provided in the contacting holes;
wherein, the IGZO layer includes a channel region, a source region and a drain region which are self-aligned with the gate electrode, and resistance of the source region and resistance of drain region are smaller than that of the channel region.

10. The TFT array substrate according to claim 9, wherein the source region and drain region are formed by the irradiation of UV light or light with a frequency band closed to that of UV light.

11. The TFT array substrate according to claim 9, further comprising a capacitor with an electrode located at the same metal layer with the gate electrode, and the other electrode made of the IGZO layer and located at the same metal layer with the IGZO for the TFT.

12. The TFT array substrate according to claim 9, wherein the transparent substrate is glass substrate.
